(19) United States
(12) Patent Application Publication
(10) Pub. No.: US 2016/0268283 A1
(43) Pub. Date: Sep. 15, 2016

(54) SEMICONDUCTOR MEMORY DEVICE AND METHOD FOR MANUFACTURING SAME

(71) Applicant: Kabushiki Kaisha Toshiba, Minato-ku (JP)

(72) Inventors: Masayuki KITAMURA, Yokkaichi (JP); Atsuko Sakata, Yokkaichi (JP); Satoshi Wakatsuki, Yokkaichi (JP); Takeshi Ishizaki, Nagoya (JP); Daisuke Ikeno, Yokkaichi (JP); Junichi Wada, Yokkaichi (JP); Kei Watanabe, Yokkaichi (JP); Shinya Okuda, Oita (JP); Hirotaka Ogihara, Yokkaichi (JP); Hiroshi Nakazawa, Yokkaichi (JP); Tomonori Aoyama, Yokkaichi (JP); Kenji Aoyama, Yokkaichi (JP); Hideaki Aochi, Yokkaichi (JP)

(73) Assignee: Kabushiki Kaisha Toshiba, Minato-ku (JP)

(21) Appl. No.: 14/795,516

(22) Filed: Jul. 9, 2015

Related U.S. Application Data
(60) Provisional application No. 62/132,187, filed on Mar. 12, 2015.

(51) Int. Cl. H01L 27/115

(52) U.S. Cl. CPC H01L 27/11568; H01L 27/11582

(57) ABSTRACT

According to one embodiment, a semiconductor memory device includes a stacked body including a plurality of electrode layers; a first electrode layer included in the plurality of electrode layers; a second electrode layer included in the plurality of electrode layers; a first insulating layer provided between the first electrode layer and the second electrode layer, and provided in contact with the first electrode layer and the second electrode layer; a semiconductor portion; a charge storage film; a first conductive film; and second conductive film. The first conductive film is provided between the first electrode layer and the charge storage film, and provided in contact with the first insulating layer. The second conductive film is provided between the second electrode layer and the charge storage film, and provided in contact with the first insulating layer.

This application is based upon and claims the benefit of priority from U.S. Provisional Patent Application 62/132,187 field on Mar. 12, 2015; the entire contents of which are incorporated herein by reference.

### FIELD

Embodiments described herein relate generally to a semiconductor memory device and a method for manufacturing same.

### BACKGROUND

A memory device having a three-dimensional structure has been proposed, in which memory holes are formed in a stacked body including a plurality of electrode layers that function as control gates in memory cells and are stacked via an insulating layer, and a silicon body serving as a channel is provided on a side wall of the memory hole via a charge storage film.

There is a concern that when the memory cell is formed, the properties may be deteriorated due to oxidation or the like of the electrode layer.

### BRIEF DESCRIPTION OF THE DRAWINGS

FIG. 1 is a schematic perspective view of a memory cell array of an embodiment;

FIGS. 2A and 2B are schematic cross-sectional views of a part of the memory cell array of a first embodiment;

FIGS. 3A and 3B are enlarged schematic cross-sectional views of a part of the columnar portion of the embodiment;

FIG. 4A to FIG. 6 are schematic cross-sectional views showing a method for manufacturing the semiconductor memory device of the first embodiment;

FIG. 7A is a schematic cross-sectional view of a part of the memory string of a second embodiment and FIG. 7B is an enlarged schematic cross-sectional view of a part of the memory string of the second embodiment;

FIGS. 8A and 8B are schematic cross-sectional views showing a method for manufacturing the semiconductor memory device of the second embodiment;

FIG. 9 is a schematic cross-sectional view of a part of the memory string of a third embodiment;

FIGS. 10A to 11B are schematic cross-sectional views showing a method for manufacturing the semiconductor memory device of the third embodiment;

FIG. 12A is a schematic cross-sectional view of a part of the memory string of a fourth embodiment and FIG. 12B is an enlarged schematic cross-sectional view of a part of the memory string of the fourth embodiment; and

FIGS. 13A and 13B are schematic cross-sectional views showing a method for manufacturing the semiconductor memory device of the fourth embodiment;

### DETAILED DESCRIPTION

According to one embodiment, a semiconductor memory device includes a stacked body including a plurality of electrode layers containing a metal and separately stacked each other; a first electrode layer included in the plurality of electrode layers; a second electrode layer included in the plurality of electrode layers, and separated immediately above the first electrode layer; a first insulating layer provided between the first electrode layer and the second electrode layer, and provided in contact with the first electrode layer and the second electrode layer; a semiconductor portion provided in the stacked body, and extending in a stacking direction of the stacked body; a charge storage film provided between the semiconductor portion and the plurality of electrode layers, and extending in the stacking direction; a first conductive film; and second conductive film. The first conductive film is provided between the first electrode layer and the charge storage film, and provided in contact with the first insulating layer. The second conductive film is provided between the second electrode layer and the charge storage film, and provided in contact with the first insulating layer.

Hereinafter, embodiments will be described with reference to the drawings. In the drawings, the same elements are denoted by the same reference sign.

### First Embodiment

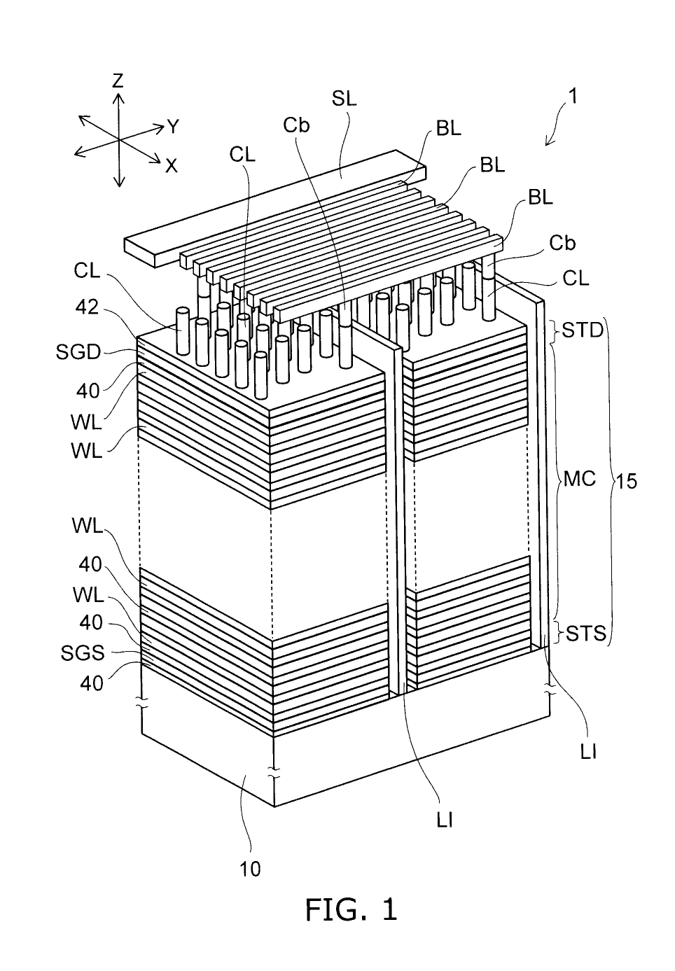

FIG. 1 is a schematic perspective view of a memory cell array 1 of an embodiment. Incidentally, in FIG. 1, in order to make the drawing easily viewable, an illustration of insulating layers between electrode layers, and the like is omitted.

In FIG. 1, two directions orthogonal to each other are defined as an X-direction and a Y-direction, and a direction, which is orthogonal to these X-direction and Y-direction (XY-plane), and in which the plurality of layers of electrode layers WL are stacked, is defined as a Z-direction (a stacking direction).

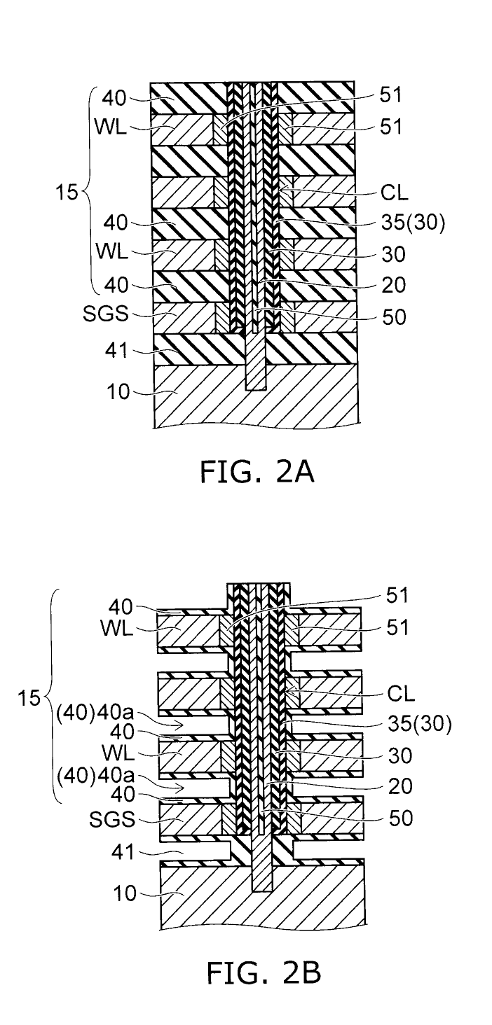

FIGS. 2A and 2B are schematic cross-sectional views of a part of the memory cell array 1 of the embodiment. In FIGS. 2A and 2B, an illustration of a structure above a stacked body 15 is omitted.

As shown in FIGS. 1, 2A, and 2B, the memory cell array 1 includes a substrate 10, a stacked body 15, the plurality of columnar portions CL, interconnect portions LI, and upper layer interconnects. In FIG. 1, as the upper layer interconnects, bit lines BL and a source layer SL are shown.

On the substrate 10, a source-side select gate SGS is provided through an insulating layer 41. On the source-side select gate SGS, the stacked body 15 is provided. On the stacked body 15, a drain-side select gate SGD is provided.

The stacked body 15 includes the plurality of electrode layers WL and the plurality of insulating layers 40 (insulating portions). The plurality of electrode layers WL is separately stacked each other. Each of the plurality of insulating layers 40 is provided between the plurality of electrode layers WL. The insulating layer 40 is provided as the uppermost layer and the lowermost layer of the stacked body 15.

For example, the plurality of electrode layers WL and the plurality of insulating layers 40 are each alternately stacked. The insulating layer 40 (first insulating layer) is provided between, for example, the stacked electrode layer WL (a first electrode layer) and the electrode layer WL (a second electrode layer) immediately above the first electrode layer, and in contact with the first electrode layer and the second electrode layer.

Incidentally, the number of layers of the electrode layers WL shown in the drawing is merely an example, and the number of the electrode layers WL may be arbitrary.

The source-side select gate SGS, the drain-side select gate SGD, and the electrode layer WL contain a metal. The source-side select gate SGS, the drain-side select gate SGD, and the electrode layer WL contain, for example, at least either one of tungsten and molybdenum, and may also contain a metal silicide.

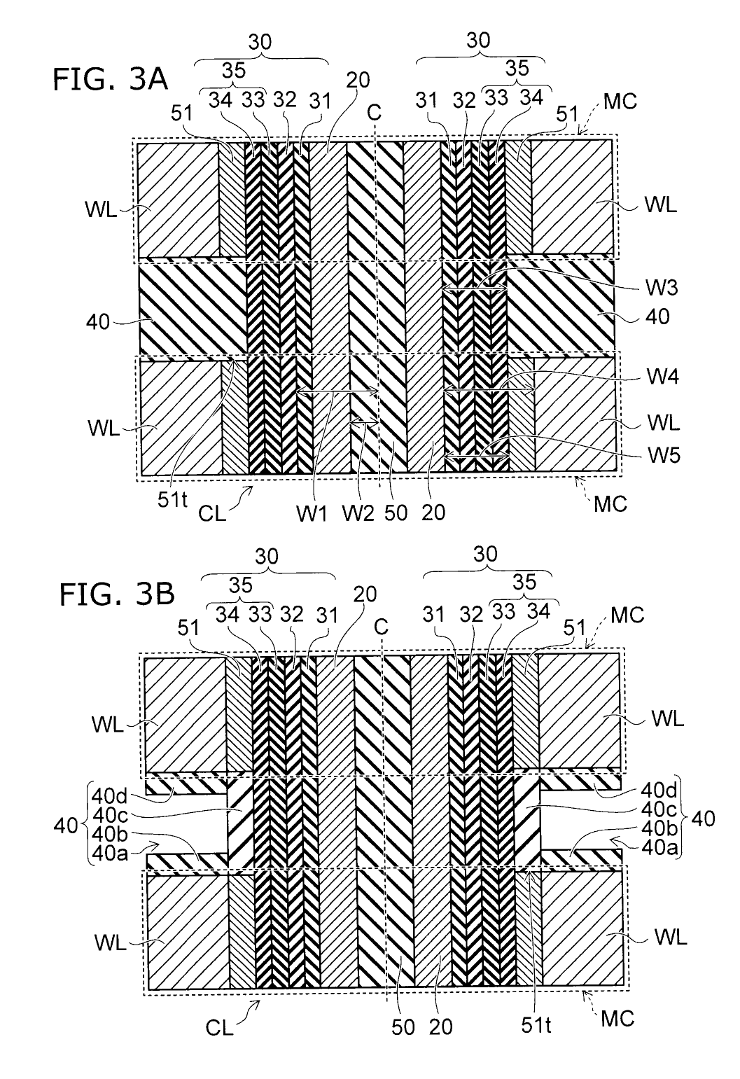

The insulating layer 40 mainly contains, for example, silicon. As shown in FIGS. 2B and 3B, for example, the insulating layer 40 may include a gap 40a (an air gap). That is, between the plurality of electrode layers WL, an air gap may be present.

The thickness of the drain-side select gate SGD and the thickness of the source-side select gate SGS may be larger than the thickness of one electrode layer WL, and, for example, a plurality of layers of the drain-side select gate SGD and the source-side select gate SGS may be provided. Incidentally, the thickness of the drain-side select gate SGD and the thickness of the source-side select gate SGS may be equal or less than the thickness of one electrode layer WL, in which case a plurality of layers of layers of the drain-side select gate SGD and the source-side select gate SGS may be provided similarly to the above. Incidentally, the “thickness” as used herein refers to a thickness in the stacking direction (Z-direction) of the stacked body 15.

In the stacked body 15, the plurality of columnar portions CL extending in the Z-direction are provided. The columnar portion CL is provided in the shape of, for example, a circular cylinder or an elliptical cylinder. The plurality of columnar portions CL is arranged, for example, in a hound's-tooth check pattern. Alternatively, the plurality of columnar portions CL may be arranged in a square grid pattern along the X-direction and Y-direction. The columnar portions CL are electrically connected to the substrate 10.

The columnar portion CL includes a channel body 20, a memory film 30, and a core insulating film 50 shown in FIG. 3A. The memory film 30 is provided between the stacked body 15 and the channel body 20.

The memory film 30 and the channel body 20 extend along the Z-direction without substantially forming a level difference. Due to this, a distance W1 between a center axis c of the columnar portion CL and the memory film 30 shows a tendency that it is substantially equal, constantly increases, or constantly decreases in the Z-direction. Further, a distance W2 between the center axis c of the columnar portion CL and the channel body 20 shows a tendency that it is substantially equal, constantly increases, or constantly decreases in the Z-direction. That is, the memory film 30 and the channel body 20 extend in the Z-direction and do not extend in the X-Y plane.

The core insulating film 50 is provided on the inside of the channel body 20. Incidentally, the channel body 20 may be in the form of, for example, a cylinder. On the inside of the channel body 20, for example, the core insulating film 50 may not be provided.

The channel body 20 is, for example, a silicon film containing silicon as a main component. The core insulating film 50 includes, for example, a silicon oxide film, and may include an air gap.

The stacked body 15 is provided with a interconnect portion LI extending in the X-direction and Z-direction in the stacked body 15. The interconnect portion LI is interposed by the stacked bodies 15. On a side wall of the interconnect portion LI, an insulating film is provided. On the inside of the insulating film, a conductive film is provided. The insulating film and the conductive film extend in the X-direction and Z-direction in the same manner as the interconnect portion LI.

A lower end of the interconnect portion LI is electrically connected to the channel body 20 (semiconductor portion) in the columnar portion CL through the substrate 10. An upper end of the interconnect portion LI is electrically connected to a peripheral circuit through an interconnect (not shown). The interconnect portion LI is electrically connected to a control circuit (not shown) via a contact layer provided on the interconnect portion LI.

Incidentally, the interconnect portion LI may be provided between the substrate 10 and the stacked body 15.

On the stacked body 15, the plurality of bit lines BL (for example, metal films) is provided. The plurality of bit lines BL is spaced apart from each other in the X-direction and extends in the Y-direction.

An upper end of the channel body 20 is electrically connected to the bit lines BL (interconnects) shown in FIG. 1, and the lower end side of the channel body 20 is connected to the substrate 10. The respective bit lines BL extend in the Y-direction.

The plurality of columnar portions CL is configured such that the plurality of channel bodies 20 selected one by one from respective regions spaced apart from each other in the Y-direction are connected to one common bit line BL.

In an upper end portion of the columnar portion CL, a drain-side selection transistor STD is provided, and on a lower end portion thereof, a source-side selection transistor STS is provided.

The memory cell MC, the drain-side selection transistor STD, and the source-side selection transistor STS are vertical transistors in which an electrical current flows in the stacking direction (Z-direction) of the stacked body 15.

The respective select gates SGD and SGS function as gate electrodes (control gates) for the selection transistors STD and STS, respectively. Between the channel body 20 and each of the select gates SGD and SGS, an insulating film (a memory film 30) which functions as a gate insulating film for each of the selection transistors STD and STS is provided.

Between the drain-side selection transistor STD and the source-side selection transistor STS, the plurality of memory cells MC using the respective layers of the plurality of electrode layers WL as control gates is provided.

The plurality of memory cells MC, the drain-side selection transistor STD, and the source-side selection transistor STS are connected in series through the channel body 20 to form one memory string. By disposing this memory string in, for example, a hound's-tooth check pattern in a plane direction parallel to the X-Y plane, the plurality of memory cells MC is three-dimensionally provided in the X-direction, Y-direction, and Z-direction.

The semiconductor memory device of the embodiment can electrically and freely erase and write data, and also can maintain stored contents even when the power is turned off.

FIG. 3A is an enlarged schematic cross-sectional view of a part of the columnar portion CL of the embodiment. By using FIG. 3A, an example of the memory cell MC of the embodiment will be described.

The memory cell MC is, for example, a charge trap type memory cell, and includes the electrode layer WL, a conductive film 51, the memory film 30, the channel body 20, and the core insulating film 50.

Between the columnar portion CL and the electrode layer WL, a conductive film 51 is provided. Between the electrode layer WL and the core insulating film 50, the memory film 30 and the channel body 20 are provided. On the inside of the channel body 20, for example, the core insulating film 50 is provided.

The channel body 20 functions as a channel in the memory cell MC, and the electrode layer WL functions as a control gate of the memory cell MC. A charge storage film 32 functions as a data storage layer which stores electrical charges injected from the channel body 20. That is, at each of crossing portions between the channel body 20 and the electrode layers WL, the memory cell MC including a structure in which the control gate surrounds the channel is formed.

The memory film 30 includes, for example, a block insulating film 35, the charge storage film 32, and a tunnel insulating film 31. The block insulating film 35 is in contact with the conductive film 51 (described below), the tunnel insulating film 31 is in contact with the channel body 20, and the charge storage film 32 is provided between the block insulating film 35 and the tunnel insulating film 31.

The block insulating film 35 prevents electrical charges stored in the charge storage film 32 from diffusing to the electrode layer WL. The block insulating film 35 contains, for example, at least any one of hafnium, aluminum, zirconium, and lanthanum, and contains a material (a high dielectric constant oxide film: a high-k film) having a higher dielectric constant than a silicon nitride film.

The block insulating film 35 includes, for example, a cap film 34 and a block film 33. The block film 33 is provided between the cap film 34 and the charge storage film 32. The block film 33 is, for example, a silicon oxide film.

The cap film 34 is provided in contact with the conductive film 51. The cap film 34 uses a film having a higher dielectric constant than the block film 33, and contains, for example, at least any one of hafnium, aluminum, zirconium, and lanthanum described above. The cap film 34 includes, for example, at least either one of a silicon nitride film and aluminum oxide film. By providing the cap film 34 in contact with the conductive film 51, it is possible to suppress back tunneling electrons injected from the electrode layer WL in erasing. That is, by using a stacked film composed of a silicon oxide film and either one of a silicon nitride film and a high dielectric constant oxide film as the block insulating film 35, the electrical charge blocking property can be enhanced.

The charge storage film 32 contains a lot of trap sites to trap charge, and is, for example, a silicon nitride film.

The tunnel insulating film 31 serves as a potential barrier when charge is injected from the channel body 20 into the charge storage film 32 or when the charge stored in the charge storage film 32 diffuses into the channel body 20. The tunnel insulating film 31 is, for example, a silicon oxide film.

Alternatively, as the tunnel insulating film 31, a stacked film (ONO film) including a structure in which a silicon nitride film is interposed between a pair of silicon oxide films may be used. When the ONO film is used as the tunnel insulating film 31, an erase operation can be performed at a low electric field, compared to a single layer of silicon oxide film.

As shown in FIG. 2A, the plurality of conductive films 51 (conductive portions) is provided for the respective layers of the plurality of electrode layers WL, and is in contact with a side surface of the electrode layer WL and a side surface of the columnar portion CL. The conductive films 51 are electrically connected to the electrode layers WL.

The conductive films 51 are not provided on a side surface of the insulating layer 40, and are stacked in the Z-direction separated from each other via the insulating layer 40 in the same manner as the electrode layers WL. The plurality of conductive films 51 is provided between the plurality of insulating layers 40 (the first insulating layer and the second insulating layer), and in contact with the plurality of insulating layers 40.

For example, a nitrogen concentration of the conductive film 51 is higher than a nitrogen concentration of the insulating layer 40. Incidentally, the nitrogen concentration is expressed as, for example, the number of nitrogen atoms per unit volume (atm/cm³).

The side surface of the electrode layer WL is completely covered by the conductive film 51 and is separated from the columnar portion CL via the conductive film 51. The upper and lower surfaces of the electrode layer WL are in contact with the insulating layer 40.

The conductive film 51 includes, for example, a metal nitride film containing a metal which is the same as the metal of the electrode layer WL. The conductive film 51 may include, for example, a metal silicide film (a film containing a metal and silicon) containing a metal which is the same as the metal of the electrode layer WL.

As shown in FIG. 3A, a distance W3 between the insulating layer 40 and the channel body 20 is smaller than a distance W4 between the electrode layer WL and the channel body 20. Further, a distance W5 between the conductive film 51 and the channel body 20 is smaller than the distance W4 and not smaller than the distance W3.

As shown in FIG. 3B, the conductive film 51 is provided, for example, extending in the stacking direction, and includes an upper surface 51t in contact with the insulating layer 40. A face in contact with the insulating layer 40 of the electrode layer WL is coplanar with a face in contact with the insulating layer 40 of the upper surface 51t of the conductive film 51. That is, a height of the electrode layer WL in contact with the insulating layer 40 is almost equal to a height of the conductive film 51 in contact with the insulating layer 40.

The insulating layer 40 includes, for example, a gap 40a, a first insulating portion 40b, a second insulating portion 40c, and a third insulating portion 40d. The first insulating portion 40b is in contact with an upper surface of the electrode layer WL (first electrode layer) provided under the insulating layer 40. The second insulating portion 40c is in contact with an upper surface of the conductive film 51 (first conductive film) provided under the insulating layer 40 and a lower surface of the conductive film 51 (second conductive film) provided on the insulating layer 40, and extends in the Z-direction. The third insulating portion 40d is in contact with a lower surface of the electrode layer WL (second electrode layer) provided on the insulating layer 40. The third insulating portion 40d is separated from the first insulating portion 40b. The third insulating portion 40d is connected to the first insulating portion 40b through the second insulating portion 40c.

The insulating film 51 is provided in the same manner as described above also between, for example, the columnar portion CL and each of the select gates (the source-side select gate SGS and the drain-side select gate SGD).

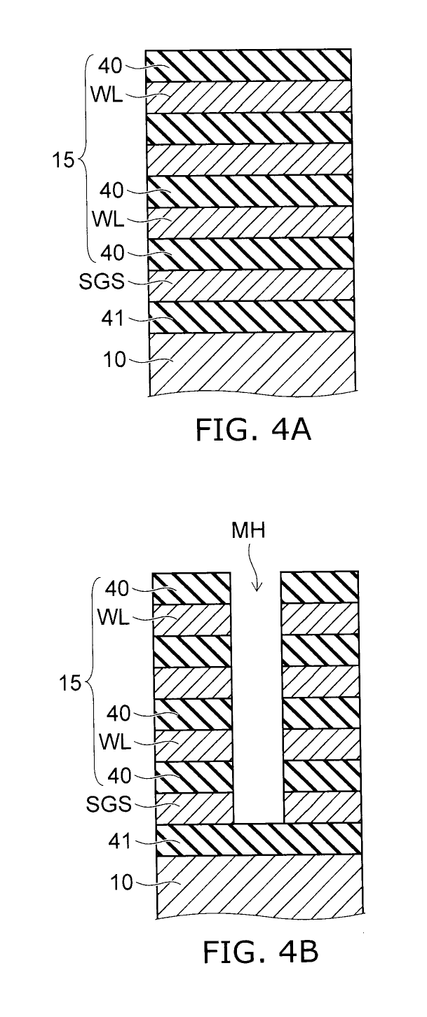

Next, with reference to FIG. 4A to FIG. 6, an example of a method for manufacturing a semiconductor memory device of the embodiment will be described.

As shown in FIG. 4A, on a substrate 10, a source-side select gate SGS is formed through the insulating layer 41. On the source-side select gate SGS, a stacked body 15 is formed, the stacked body 15 includes the plurality of electrode layers WL and the plurality of insulating layers 40. The plurality of electrode layers WL is stacked on each other through the insulating layer 40. For example, on the source-side select gate SGS, the plurality of insulating layers 40 and the plurality of electrode layers WL are alternately formed one by one, respectively. The insulating layer 40 is formed as the uppermost layer and the lowermost layer of the stacked body 15. The number of the stacked layers in the stacked body 15 is arbitrary.

The source-side select gate SGS and the electrode layer WL contain, for example, a metal, and contain, for example, at least either one of tungsten and molybdenum. Each of the insulating layers 40 and 41 include, for example, a silicon oxide film.

Thereafter, on the stacked body 15, a drain-side select gate SGD shown in FIG. 1 is formed. As shown in FIG. 4B, a memory hole MH passing through the stacked body 15 and reaching the insulating layer 40 is formed. The memory hole MH is formed by, for example, an RIE method (Reactive Ion Etching) using a mask (not shown). On a side wall of the memory hole MH, a side surface of the electrode layer WL and a side surface of the insulating layer 40 are exposed. On a bottom surface of the memory hole MH, the insulating layer 41 is exposed.

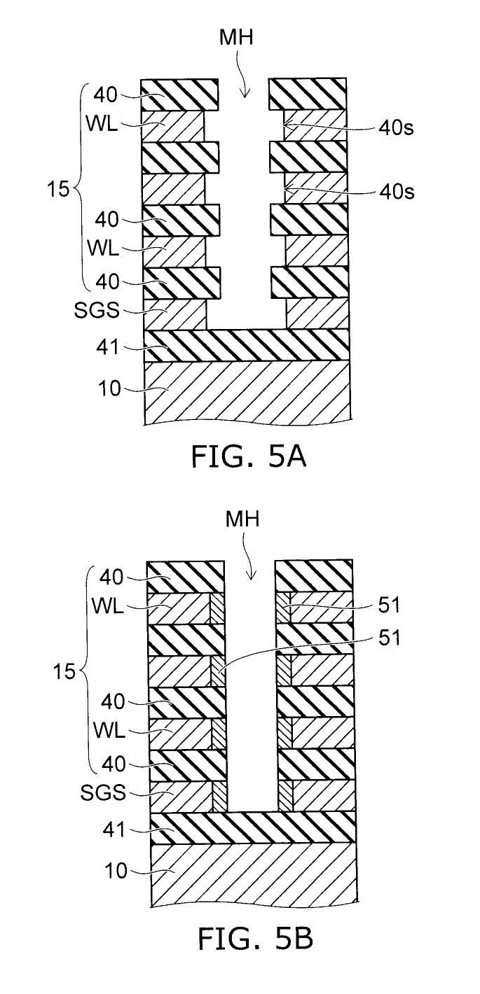

As shown in FIG. 5A, for example, the electrode layers WL are recessed through the memory hole MH. As a method for recessing the electrode layers WL, for example, etching using a chemical liquid or etching using a gas containing a halogen such as nitrogen trifluoride (NF₃) or chlorine trifluoride (CIF₃) is used. According to this, in a portion where the electrode layer WL is recessed, a concave space 40s is formed.

The space 40s is formed integrally with the memory hole MH and is interposed between the insulating layers 40 formed in the Z-direction. The space 40s is formed on the outer side of the memory hold MH from the side surface of the insulating layer 40 exposed to the memory hole MH. In the space 40s, for example, the upper and lower surfaces of the insulating layer 40 and also the side surface of the electrode layer WL are exposed.

As shown in FIG. 5B, through the memory hole MH, in the space 40s, the conductive film 51 is formed. As a method for forming the conductive film 51, for example, a thermal annealing using ammonia (NH₃) gas or nitrogen (N₂) gas is used. According to this, the conductive film 51 can be selectively formed, and thus, it becomes possible to form the conductive film 51 on the side surface of the electrode layer WL exposed to the space 40s. At this time, as the conductive film 51, a nitride film of the metal used in the electrode layer WL is formed.

Incidentally, as a method for forming the conductive film 51, for example, a thermal annealing using silane (SiH₄) gas or disilane (Si₂H₆) gas is used. In the same manner as the above-described thermal annealing, the conductive film 51 can be selectively formed. At this time, as the conductive film 51, a silicide film (a film containing a metal and silicon) of the electrode layer WL is formed.

The side surface of the conductive film 51 exposed to the memory hole MH is formed on the outer side of the memory hole MH from the side surface of the insulating layer 40 or formed so as to be flat with the side surface of the insulating layer 40.

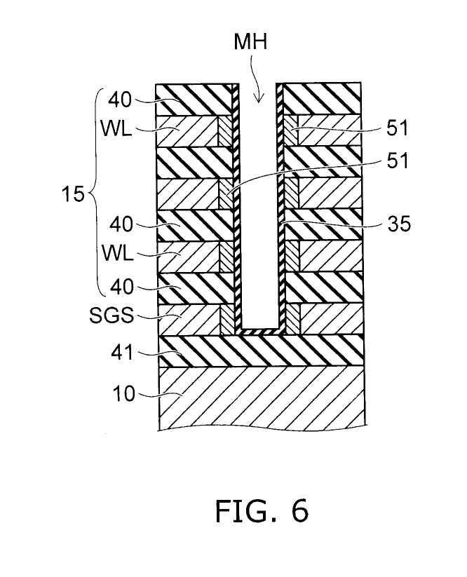

As shown in FIG. 6, on the side wall (side surface and bottom surface) of the memory hole MH, the block insulating film 35 is formed. As a method for forming the block insulating film 35, for example, an ALD (Atomic Layer Deposition) method using ozone gas or water vapor is used. Incidentally, the side surface of the electrode layer WL is covered by the conductive film 51 and is not exposed to the memory hole MH. For example, the block insulating film 35 may be formed in the space 40s.

Thereafter, on the inside of the block insulating film 35, a charge storage film 32 and a tunnel insulating film 31 shown in FIG. 3A are formed. Subsequently, the bottom surface of the memory hole MH is made to pass through to reach the substrate 10, and then, a channel body 20 is formed.

Thereafter, as shown in FIG. 2A, for example, on the inside of the channel body 20, a core insulating film 50 is formed. That is, a columnar portion CL electrically connected to the substrate 10 is formed. Incidentally, the conductive film 51 does not protrude to the columnar portion CL. Thereafter, for example, as shown in FIG. 2B, a gap 40a may be formed in the insulating layer 40.

Subsequently, a source layer SL, bit lines BL, and the like shown in FIG. 1 are formed, and thus, the semiconductor memory device of the embodiment is formed.

According to the embodiment, in the process of forming the columnar portion CL, the conductive film 51 is exposed on the side wall of the memory hole MH, and the side surface of the electrode layer WL is not exposed. The insulating layer 40 provided in the stacked body 15 is provided between the plurality of electrode layers WL, and in contact with the plurality of electrode layers WL. The conductive film 51 is provided between the plurality of insulating layers 40, and in contact with the plurality of insulating layers 40. According to this, it is possible to prevent oxidation or nitriding of the electrode layer WL when the block insulating film 35 of the columnar portion CL is formed.

In addition to the above description, the conductive film 51 is formed, for example, in the space 40s. Due to this, it is possible to form the conductive film 51 so as not to protrude to the memory hole MH side from the side surface of the insulating layer 40. According to this, it is possible to form the conductive film 51 which does not protrude to the columnar portion CL. That is, the conductive film 51 can be formed such that the diameter of the columnar portion CL is larger than in the case where the conductive film 51 is formed on the side wall of the memory hole MH. Due to this, oxidation or nitriding of the electrode layer WL can be prevented without deteriorating the property of the memory cell MC, and an increase in the resistance of the electrode layer WL can be suppressed.

Further, the columnar portion CL can be provided such that the diameter thereof is uniform in the Z-direction, and therefore, the size of a device can be decreased without locally deteriorating the property of the memory cell MC.

Incidentally, the implementation of the process of forming the spaces 40s by recessing the electrode layers WL described above is arbitrary. In such a case, by forming the conductive film 51 such that the conductive film 51 does not protrude into the memory hole MH from the side surface of the insulating layer 40, the above-described advantageous effect can be obtained.

### Second Embodiment

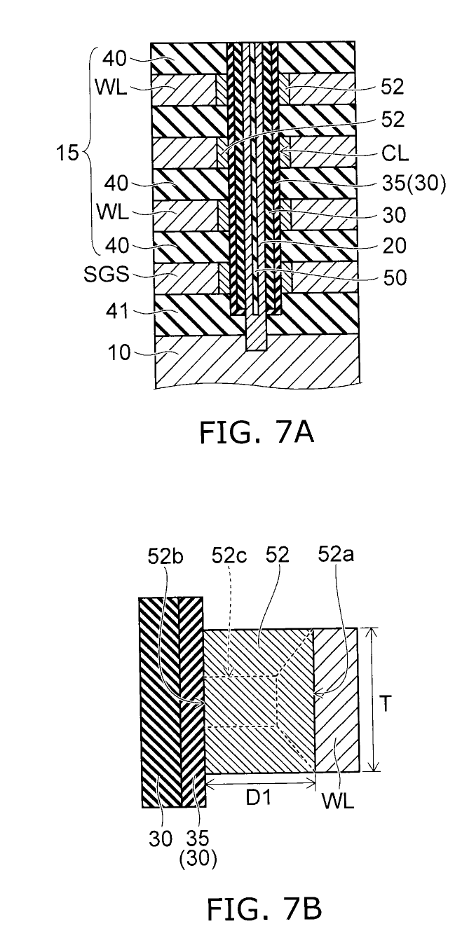

FIG. 7A is a schematic cross-sectional view of a part of a memory string MS of a second embodiment. Incidentally, also in FIGS. 7A and 7B, an illustration of a structure above a stacked body 15 is omitted. FIG. 7B is an enlarged schematic cross-sectional view of a part of the memory string MS of the second embodiment.

In the embodiment, a main difference from the embodiment described above is a method for forming a conductive film 52 and a material of a conductive film 52. Therefore, a description of the same portions as in the embodiment described above will be omitted.

As shown in FIG. 7A, between a columnar portion CL and the plurality of electrode layers WL, the plurality of conductive films 52 are provided. The conductive film 52 is provided for each layer of the electrode layers WL, and is in contact with a side surface of the electrode layer WL and a side surface of the columnar portion CL. The conductive film 52 has electrical conductivity and is electrically connected to the electrode layer WL. The conductive films 52 are not provided on a side surface of an insulating layer 40, and are stacked in the Z-direction through the insulating layer 40 in the same manner as the electrode layers WL.

The conductive film 52 contains, for example, a metal which is different from the metal of the electrode layer WL and contains a metal nitride. The conductive film 52 may contain, for example, a metal nitride of a metal which is the same as the metal of the electrode layer WL.

As shown in FIG. 7B, the conductive film 52 includes a first face 52a (a third face) in contact with the electrode layer WL and a second face 52b (a fourth face) in contact with a block insulating film 35. The second face 52b faces the first face 52a. A distance D1 between the first face 52a and the second face 52b is larger than one-half of the thickness T of the electrode layer WL in contact with the conductive film 52. According to this, in the process of forming the conductive film 52, it is possible to form the conductive film 52 which does not protrude to the memory hole MH side from the side surface of the insulating layer 40.

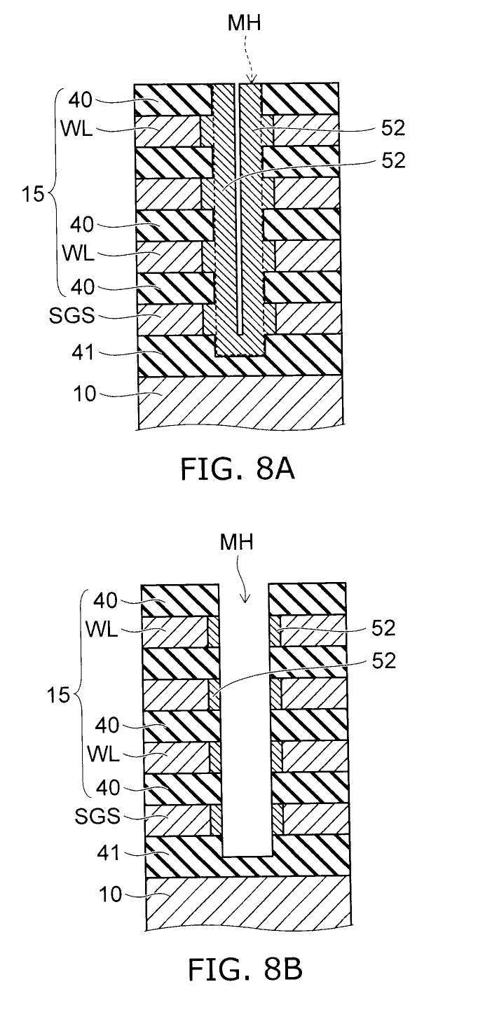

Next, with reference to FIGS. 8A and 8B, an example of a method for manufacturing a semiconductor memory device of the embodiment will be described.

In the same manner as FIGS. 4A to 5A of the first embodiment described above, on a substrate 10, a source-side select gate SGS is formed through an insulating layer 41. On the source-side select gate SGS, a stacked body 15 including plurality of electrode layers WL and the plurality of insulating layers 40 is formed.

Thereafter, on the stacked body 15, a drain-side select gate SGD shown in FIG. 1 is formed.

Subsequently, a memory hole MH passing through the stacked body 15 and reaching the insulating layer 40 is formed. On a side wall of the memory hole MH, a side surface of the electrode layer WL and a side surface of the insulating layer 40 are exposed. On a bottom surface of the memory hole, the insulating layer 41 is exposed.

Thereafter, for example, the electrode layers WL are recessed through the memory hole MH. For example, by heating the substrate 10 to 30° C. or higher and 400° C. or lower and exposing the electrode layers WL to a gas containing a halogen such as nitrogen trifluoride or chlorine trifluoride, the electrode layers WL are isotropically etched. At this time, a recessed distance of the side surface of the electrode layer WL from the side surface of the insulating layer 40 is larger than one-half of the thickness of the electrode layer WL. According to this, in a portion where the electrode layer WL is recessed, a concave space 40s is formed.

As shown in FIG. 8A, on the side wall of the memory hole MH and in the space 40s, a conductive film 52 is formed. As a method for forming the conductive film 52, for example, a CVD (Chemical Vapor Deposition) method which has favorable step coverage is used.

The thickness (a distance D1 in FIG. 7B) of the formed conductive film 52 is larger than one-half of the thickness T of the electrode layer WL. According to this, the conductive film 52 simultaneously deposited from the upper and lower surfaces of the insulating layer 40 exposed in the space 40s and from the side surface of the electrode layer WL can be completely filled in the space 40s. Further, it is possible to form the conductive film 52 which is thicker than the protruding portion including the exposed upper, lower, and side surfaces of the insulating layer, and even after a later process of removing a part of the conductive film 52 is performed, the conductive film 52 can be left in the space 40s.

The conductive film 52 may contain a metal which is the same as the metal of the electrode layer WL, or may contain a metal which is different from the metal of the electrode layer WL. The conductive film 52 includes, for example, a metal nitride film of tungsten nitride, molybdenum nitride, or the like.

The conductive film 52 includes, for example, a metal nitride layer having a composition of a metal atom M and a nitrogen atom N represented by M2N (atomic number ratio=0.5) or MN (atomic number ratio=1.0) and a mixture thereof. For example, the atomic number ratio of nitrogen atom N to metal atom M is 0.1 or more and 2.0 or less.

For example, the conductive film 52 contains titanium nitride. At this time, titanium nitride is formed by a CVD method using titanium tetrachloride (TiCl₄) as a material gas and ammonia as a reducing gas and heating the substrate 10 to 250° C. or higher and 650° C. or lower. For example, the electrode layer WL may be corroded by ammonia. However, the deposition temperature of a titanium nitride film is 250° C. or higher as described above, and is lower than the deposition temperature of a block insulating film 35 described below. Therefore, the degree of corrosion of the electrode layer WL by ammonia is lower than the degree of corrosion of the electrode layer WL by the formation of the block insulating film 35.

As shown in FIG. 8B, the conductive film 52 formed other than in the space 40s is removed. As a method for removing the conductive film 52, for example, the same method as in the case where the electrode layers WL are recessed is used, and by heating the substrate 10 to 30° C. or higher and 400° C. or lower and exposing the conductive film 52 to a gas containing a halogen such as nitrogen trifluoride or chlorine trifluoride, the conductive film 52 is isotropically etched.

In the above etching, a chemical liquid may be used in place of a gas, and an etching method is arbitrary.

Thereafter, as shown in FIG. 7A, on the side wall of the memory hole MH, the block insulating film 35 is formed. As a method for forming the block insulating film 35, for example, a CVD method is used. The block insulating film 35 includes, for example, at least either one of a silicon oxide film and a silicon nitride film. At this time, in the same manner as the embodiment described above, the side surface of the electrode layer WL is covered by the conductive film 52 and is not exposed to the memory hole MH. Due to this, the electrode layer WL is not oxidized or nitrided by a gas (for example, ammonia, ozone, or the like) to be used for forming the block insulating film 35.

On the inside of the block insulating film 35, in the same manner as the embodiment described above, the respective films (a charge storage film 32, a channel body 20, and the like) shown in FIG. 3A are formed, and a columnar portion CL electrically connected to the substrate 10 is formed. At this time, the conductive film 52 does not protrude to the columnar portion CL. Thereafter, for example, in the same manner as shown in FIG. 2B described above, a gap 40a may be formed in the insulating layer 40.

Thereafter, a source layer SL, bit lines BL, and the like shown in FIG. 1 are formed, and thus, the semiconductor memory device of the embodiment is formed.

According to the embodiment, in the same manner as the embodiment described above, the conductive film 52 is formed on the side surface of the electrode layer WL, and the side surface of the electrode layer WL is not exposed to the memory hole MH. The insulating layer 40 provided in the stacked body 15 is provided between the plurality of electrode layers WL, and in contact with the plurality of electrode layers WL. The conductive film 52 is provided between the plurality of insulating layers 40, and in contact with the plurality of insulating layers 40. According to this, it is possible to prevent oxidation or nitriding of the electrode layer WL when the block insulating film 35 is formed.

In addition to the above description, the conductive film 52 is formed in the space 40s, and does not protrude into the memory hole MH. According to this, it is possible to form the conductive film 52 without decreasing the diameter of the columnar portion CL. Due to this, oxidation or nitriding of the electrode layer WL can be prevented without deteriorating the property of the memory cell MC, and an increase in the resistance of the electrode layer WL can be suppressed.

Further, the columnar portion CL can be provided such that the diameter thereof is uniform in the Z-direction, and therefore, the size of a device can be decreased without deteriorating the property of the memory cell MC.

Further, in the process of recessing the electrode layers WL, a recessed distance of the electrode layer WL from the side surface of the insulating layer 40 is larger than one-half of the thickness of the electrode layer WL. According to this, the conductive film 52 can be completely filled in the space 40s, and thus, oxidation or nitriding of the electrode layer WL can be prevented without deteriorating the property of the memory cell MC, and an increase in the resistance of the electrode layer WL can be suppressed.

Further, according to the embodiment, for example, titanium nitride is used as the conductive film 52. For example, the titanium nitride film has a crystal structure in the columnar crystal form in which a grain boundary is formed in a growing direction, and this structure causes a metal or the like to diffuse, and therefore, a sufficient barrier property may not be able to be obtained. On the other hand, according to the embodiment, the conductive film 52 is deposited from the lower surface and the upper surface of the insulating layer 40. Therefore, the grain boundary of the conductive film 52 is formed in the stacking direction (Z-direction). Due to this, in the thermal annealing when forming the block insulating film 35 or the like, the diffusion of the metal included in the electrode layer WL is blocked at the grain boundary of the conductive film 52, and the metal is prevented from reaching the block insulating film 35. According to this, oxidation or nitriding of the electrode layer WL can be prevented without locally deteriorating the property of the memory cell MC, and an increase in the resistance of the electrode layer WL can be suppressed.

### Third Embodiment

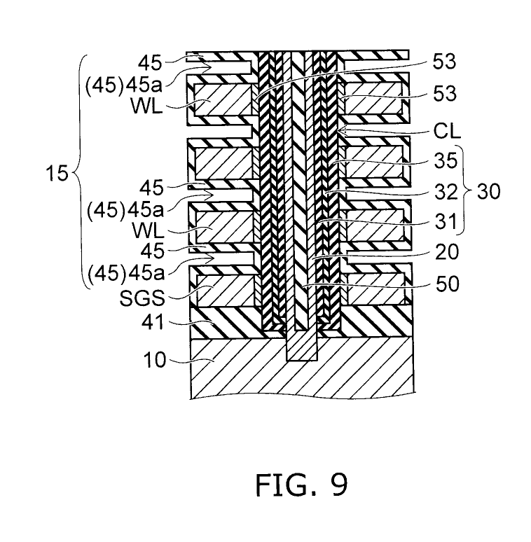

FIG. 9 is a schematic cross-sectional view of a part of a memory string MS of a third embodiment. Incidentally, in FIG. 9, an illustration of a structure above a stacked body 15 is omitted.

In the embodiment, a main difference from the embodiments described above is a method for forming a conductive film 53 and a configuration of the conductive film 53. Therefore, a description of the same portions as in the embodiments described above will be omitted.

As shown in FIG. 9, between a columnar portion CL and the plurality of electrode layers WL, the plurality of conductive films 53 are provided. The conductive film 53 is provided for each layer of the electrode layers WL, and is in contact with a side surface of the electrode layer WL and a side surface of the columnar portion CL. The conductive film 53 has electrical conductivity and is electrically connected to the electrode layer WL. The conductive films 53 are not provided on a side surface of an insulating layer 40, and are stacked in the Z-direction through the insulating layer 40 in the same manner as the electrode layers WL.

The conductive film 53 is a metal nitride containing a metal which is the same as the metal of the electrode layer WL. The electrode layer WL contains, for example, at least any one of titanium, cobalt, nickel, copper, molybdenum, ruthenium, and tungsten. The electrode layer WL may contain, for example, a metal nitride containing a material described above, or a metal silicide containing a material described above.

The conductive film 53 includes, for example, a metal nitride layer having a composition of a metal atom M and a nitrogen atom N represented by M2N (atomic number ratio=0.5) or MN (atomic number ratio=1.0) and a mixture thereof. For example, the atomic number ratio of nitrogen atom N to metal atom M is 0.1 or more and 2.0 or less.

For a block insulating film 35 to be in contact with the conductive film 53, a material having a higher dielectric constant than a silicon nitride film is used, and contains, for example, at least any one of hafnium, aluminum, zirconium, and lanthanum. An insulating layer 45 includes, for example, a silicon oxide film, and includes a gap 45a.

The conductive film 53 does not protrude to the columnar portion CL, and the columnar portion CL does not protrude to the conductive film 53.

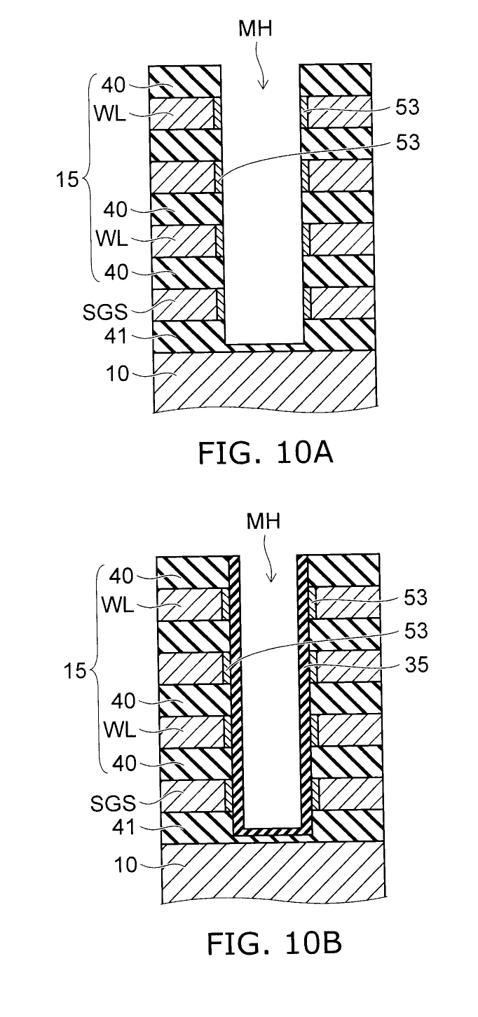

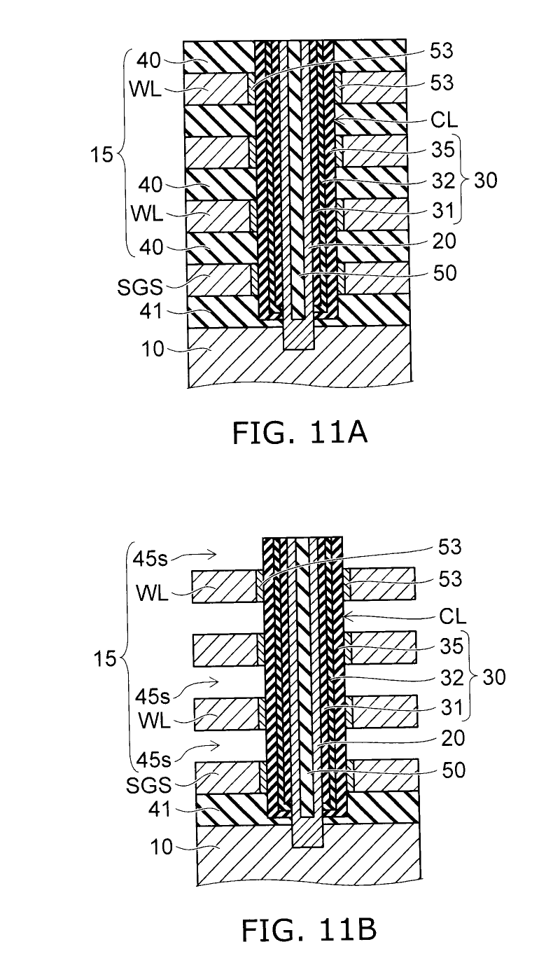

Next, with reference to FIGS. 10A to 11B, an example of a method for manufacturing a semiconductor memory device of the embodiment will be described.

In the same manner as FIGS. 4A and 4B of the first embodiment described above, on a substrate 10, a source-side select gate SGS is formed through an insulating layer 41. On the source-side select gate SGS, a stacked body 15 including the plurality of electrode layers WL and the plurality of insulating layers 40 is formed.

Thereafter, on the stacked body 15, a drain-side select gate SGD shown in FIG. 1 is formed.

Subsequently, a memory hole MH passing through the stacked body 15 and reaching the insulating layer 40 is formed. On a side wall of the memory hole MH, a side surface of the electrode layer WL and a side surface of the insulating layer 40 are exposed. On a bottom surface of the memory hole MH, the insulating layer 41 is exposed.

As shown in FIG. 10A, on a side surface of the electrode layer WL exposed on the side wall of the memory hole MH, a conductive film 53 is formed. The conductive film 53 is formed by, for example, nitriding the side surface of the electrode layer WL by a plasma treatment through the memory hole MH. According to this, the side surface of the electrode layer WL is completely covered by the conductive film 53 and is not exposed to the memory hole MH.

As shown in FIG. 10B, on the side wall of the memory hole MH, a block insulating film 35 is formed. The block insulating film 35 is formed in contact with a side surface of the conductive film 53. The block insulating film 35 contains, for example, at least any one of hafnium, aluminum, zirconium, and lanthanum. The block insulating film 35 includes, for example, a stacked film (for example, a cap film and a block film) containing a material described above. Incidentally, by allowing the conductive film 53 to function as a barrier metal (an anti-oxidation metal), on the side wall of the memory hole MH, a high dielectric constant oxide film can be directly formed.

As shown in FIG. 11A, on the inside of the block insulating film 35, in the same manner as the embodiments described above, the respective films (a charge storage film 32, a channel body 20, and the like) shown in FIG. 3A are formed, and a columnar portion CL electrically connected to the substrate 10 is formed.

The charge storage film 32 includes, for example, a silicon nitride film, hafnium oxide film, or the like, and the tunnel insulating film 31 includes, for example, a silicon oxide film, a silicon nitride film, a silicon oxynitride film, or the like.

As shown in FIG. 11B, a through-portion ST passing through the stacked body 15 is formed. The through-portion ST is formed in the form of, for example, a hole or a slit.

Thereafter, the insulating layer 40 is removed by isotropically etching through the through-portion ST. According to this, a space 45s is formed.

Subsequently, as shown in FIG. 9, an insulating layer 45 is formed in the space 45s, and in the inside of the insulating layer 45, a gap 45a is formed. As the insulating layer 45, for example, a silicon oxide film is used.

Thereafter, a source layer SL, bit lines BL, and the like shown in FIG. 1 are formed, and thus, the semiconductor memory device of the embodiment is formed.

According to the embodiment, in the same manner as the embodiments described above, the conductive film 53 is formed on the side surface of the electrode layer WL, and the side surface of the electrode layer WL is not exposed to the memory hole MH. The insulating layer 40 provided in the stacked body 15 is provided between the plurality of electrode layers WL, and in contact with the plurality of electrode layers WL. The conductive film 53 is provided between the plurality of insulating layers 40, and in contact with the plurality of insulating layers 40. According to this, it is possible to prevent oxidation or nitriding of the electrode layer WL when the block insulating film 35 is formed.

In addition to the above description, the conductive film 53 is formed by nitriding the side surface of the electrode layer WL, and does not protrude into the memory hole MH. According to this, it is possible to form the conductive film 53 without decreasing the diameter of the columnar portion CL. Due to this, oxidation or nitriding of the electrode layer WL can be prevented without deteriorating the property of the memory cell MC, and an increase in the resistance of the electrode layer WL can be suppressed.

Further, the columnar portion CL can be provided such that the diameter thereof is uniform in the Z-direction, and therefore, the size of a device can be decreased without locally deteriorating the property of the memory cell MC.

In addition to the above description, according to the embodiment, by forming the conductive film 53 on the side surface of the electrode layer WL, as the block insulating film 35, a material having a higher dielectric constant than a silicon nitride film can be used. Due to this, by an electric field relaxation effect, high electric field leakage when erasing can be suppressed.

Further, according to the embodiment, as the insulating layer 45 and the block insulating film 35, a silicon nitride film is not used. For example, when a silicon nitride film is used, unintended electron trapping occurs, and thus, a variation in voltage may be caused. Further, when a silicon nitride film is used, leakage between the electrode layers WL can be more liable to occur than when a silicon oxide film is used.

On the other hand, according to the embodiment, as the block insulating film 35, a material having a higher dielectric constant than a silicon nitride film is used, and as the insulating layer 45, for example, a silicon oxide film is used. Due to this, the occurrence of unintended electron trapping caused by a silicon nitride film can be suppressed. In addition, it is possible to suppress leakage between the electrode layers WL.

### Fourth Embodiment

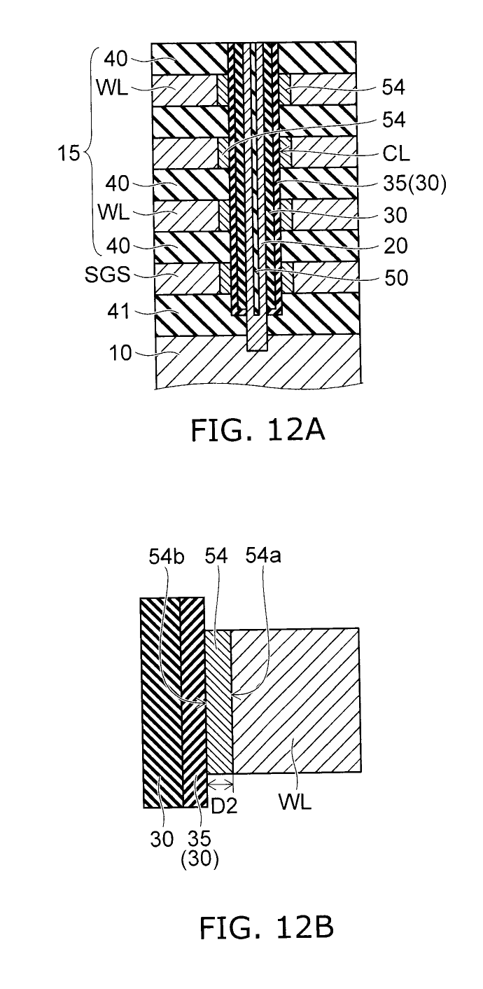

FIG. 12A is a schematic cross-sectional view of a part of a memory string MS of a fourth embodiment. Incidentally, in FIG. 12A, an illustration of a structure above a stacked body 15 is omitted. FIG. 12B is an enlarged schematic cross-sectional view of a part of the memory string of the fourth embodiment.

In the embodiment, a main difference from the embodiments described above is a method for forming a conductive film 54 and a configuration of the conductive film 54. Therefore, a description of the same portions as in the embodiments described above will be partially omitted.

As shown in FIG. 12A, between a columnar portion CL and the plurality of electrode layers WL, the plurality of conductive films 54 are provided. The conductive film 54 is provided for each layer of the electrode layers WL, and is in contact with a side surface of the electrode layer WL and a side surface of the columnar portion CL. The conductive film 54 has electrical conductivity and is electrically connected to the electrode layer WL. The conductive films 54 are not provided on a side surface of an insulating layer 40, and are stacked in the Z-direction through the insulating layer 40 in the same manner as the electrode layers WL. For example, the conductive film 54 has a higher nitrogen concentration than the insulating layer 40.

The conductive film 54 does not protrude to the columnar portion CL, and the columnar portion CL does not protrude to the conductive film 54.

The conductive film 54 is a metal nitride containing a metal which is the same as the metal of the electrode layer WL. The conductive film 54 includes, for example, a metal nitride layer having a composition of a metal atom M and a nitrogen atom N represented by M2N (atomic number ratio=0.5) or MN (atomic number ratio=1.0) and a mixture thereof. For example, the atomic number ratio of nitrogen atom N to metal atom M is 0.1 or more and 2.0 or less.

As shown in FIG. 12B, a distance D2 of the conductive film 54 is a distance (a film thickness) between a first face 54a (a third face) of the conductive film 54 in contact with the electrode layer WL and a second face 54b (a fourth face) of the conductive film 54 in contact with a block insulating film 35. The distance D2 of the conductive film 54 is, for example, 1 nm or more and 5 nm or less. The second face 54b faces the first face 54a.

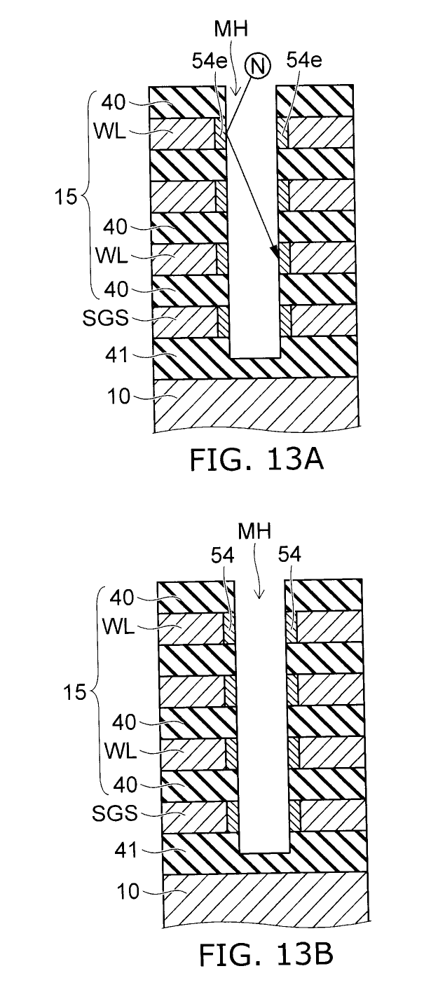

Next, with reference to FIGS. 13A and 13B, an example of a method for manufacturing a semiconductor memory device of the embodiment will be described.

In the same manner as FIGS. 4A and 4B of the first embodiment described above, on a substrate 10, a source-side select gate SGS is formed through an insulating layer 41. On the source-side select gate SGS, a stacked body 15 including the plurality of electrode layers WL and the plurality of insulating layers 40 is formed.

Thereafter, on the stacked body 15, a drain-side select gate SGD shown in FIG. 1 is formed.

Subsequently, a memory hole MH passing through the stacked body 15 and reaching the insulating layer 41 is formed. On a side wall of the memory hole MH, a side surface of the electrode layer WL and a side surface of the insulating layer 40 are exposed. On a bottom surface of the memory hole MH, the insulating layer 41 is exposed.

As shown in FIG. 13A, on a side surface of the electrode layer WL exposed on the side wall of the memory hole MH, a metal film 54e containing a nitrogen atom is formed. The metal film 54e has a higher nitrogen concentration than the electrode layer WL.

In a method for forming the metal film 54e, for example, a bias voltage is applied to the substrate 10, and a nitrogen ion generated in a plasma atmosphere is drawn into the memory hole MH. According to this, a nitrogen ion is introduced into the side surface of the electrode layer WL exposed to the memory hole MH, whereby the metal film 54e is formed. The bias voltage to be applied to the substrate 10 is, for example, 0.1 kV or more and 6.0 kV or less. The energy of the ion to be used in the above-described method is lower than that of an ion to be injected using an accelerator. Therefore, the nitrogen ion drawn into the memory hole MH is introduced into the side surface of the electrode layer WL or is reflected by the side surface and introduced into the side surface of the electrode layer WL at a deep position.

As shown in FIG. 13B, a conductive film 54 is formed in contact with a side surface of the electrode layer WL. As a method for forming the conductive film 54, for example, a thermal annealing at 700° C. or lower is used. According to this, a metal contained in the metal film 54e and a nitrogen atom are bound to each other, whereby the conductive film 54 which is a metal nitride film is formed.

As a method for forming the conductive film 54, for example, a nitrogen radical treatment may be used while heating to 700° C. or lower. In this case, nitrogen radical is brought into contact with the side surface of the electrode layer WL, and by the energy of the nitrogen radical, a nitrogen atom is introduced into the electrode layer WL. Simultaneously therewith, a metal atom and a nitrogen atom are bound to each other, whereby a metal nitride film (conductive film 54) can be formed.

The conductive film 54 includes, for example, a metal nitride layer having an atomic number ratio of nitrogen atom N to metal atom M of, for example, 0.1 or more and 2.0 or less and a mixture thereof. For example, the atomic number ratio of nitrogen atom N to metal atom M is 0.5 or more and 1.0 or less. A distance D2 of the formed conductive film 54 is, for example, 1 nm or more and 5 nm or less.

Thereafter, as shown in FIG. 12A, on the side wall of the memory hole MH, a block insulating film 35 is formed. At this time, in the same manner as the embodiments described above, the side surface of the electrode layer WL is covered by the conductive film 54 and is not exposed to the memory hole MH. Due to this, the electrode layer WL is not oxidized or nitrided by a gas or the like to be used for forming the block insulating film 35.

On the inside of the block insulating film 35, in the same manner as the embodiments described above, the respective films (a charge storage film 32, a channel body 20, and the like) shown in FIG. 3A are formed, and a columnar portion CL electrically connected to the substrate 10 is formed. At this time, the conductive film 54 does not protrude to the columnar portion CL. Thereafter, for example, in the same manner as shown in FIG. 2B described above, a gap 40a may be formed in the insulating layer 40.

Thereafter, a source layer SL, bit lines BL, and the like shown in FIG. 1 are formed, and thus, the semiconductor memory device of the embodiment is formed.

According to the embodiment, in the same manner as the embodiments described above, the conductive film 54 is formed on the side surface of the electrode layer WL, and the side surface of the electrode layer WL is not exposed to the memory hole MH. The insulating layer 40 provided in the stacked body 15 is provided between the plurality of electrode layers WL, and in contact with the plurality of electrode layers WL. The conductive film 54 is provided between the plurality of insulating layers 40, and in contact with the plurality of insulating layers 40. According to this, it is possible to prevent oxidation or nitriding of the electrode layer WL when the block insulating film 35 is formed.

In addition to the above description, the conductive film 54 is formed by nitriding of the side surface of the electrode layer WL, and does not protrude into the memory hole MH. According to this, it is possible to form the conductive film 54 without decreasing the diameter of the columnar portion CL. Due to this, oxidation or nitriding of the electrode layer WL can be prevented without deteriorating the property of the memory cell MC, and an increase in the resistance of the electrode layer WL can be suppressed.

Further, the columnar portion CL can be provided such that the diameter thereof is uniform in the Z-direction, and therefore, the size of a device can be decreased without locally deteriorating the property of the memory cell MC.

Further, according to the embodiment, the metal nitride layer of the conductive film 54 is formed such that the atomic number ratio is, for example, 0.1 or more and 2.0 or less, and the film thickness (distance D2) of the conductive film 54 is 1 nm or more and 5 nm or less. For example, the atomic number ratio of nitrogen atom N to metal atom M is 0.5 or more and 1.0 or less.

According to this, a stable metal nitride layer is formed in the conductive film 54, and a metal nitride film having high oxidation resistance is formed. Due to this, oxidation or deterioration of the electrode layer WL can be further prevented, and an increase in the resistance of the electrode layer WL can be suppressed.

Incidentally, according to the embodiment, a nitrogen radical treatment is used while heating to, for example, 700° C. or lower. At this time, as the conditions for determining the concentration and depth of a nitrogen atom to be introduced into the electrode layer WL, an effect of at least any one of an electric field intensity of a pulsed electric field, a voltage, a pressure in a plasma atmosphere, and a treatment time is large, and an effect of diffusion by heat is small. Due to this, in the case where a nitrogen radical treatment is used, a metal film having a high nitrogen concentration can be formed to have a smaller thickness as compared with a case where an annealing nitriding method is used. Incidentally, when a nitrogen atom is introduced and a metal nitride film is formed, an energy of heating the substrate in a radical treatment may be applied, and a metal nitride film may be formed while controlling the radical treatment within a temperature range of room temperature or higher and 700° C. or lower. That is, the radical treatment can also be performed without heating.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device, comprising:
a stacked body including a plurality of electrode layers containing a metal and separately stacked each other;
a first electrode layer included in the plurality of electrode layers;
a second electrode layer included in the plurality of electrode layers, and separated immediately above the first electrode layer;
a first insulating layer provided between the first electrode layer and the second electrode layer, and provided in contact with the first electrode layer and the second electrode layer;
a semiconductor portion provided in the stacked body, and extending in a stacking direction of the stacked body;
a charge storage film provided between the semiconductor portion and the plurality of electrode layers, and extending in the stacking direction;
a first conductive film provided between the first electrode layer and the charge storage film, and provided in contact with the first insulating layer; and
a second conductive film provided between the second electrode layer and the charge storage film, and provided in contact with the first insulating layer.

2. The device according to claim 1, wherein the first conductive film and the second conductive film contain a metal nitride.

3. The device according to claim 1, wherein
the first conductive film contains a metal being same as the metal of the first electrode layer, and
the second conductive film contains a metal being same as the metal of the second electrode layer.

4. The device according to claim 1, wherein the first electrode layer and the second conductive film contain at least either one of tungsten and molybdenum.

5. The device according to claim 1, wherein a nitrogen concentration of the first conductive film and the second conductive film are higher than a nitrogen concentration of the first insulating layer.

6. The device according to claim 1, wherein the first conductive film and the second conductive film contain silicon and a metal.

7. The device according to claim 1, wherein the first conductive film and the second conductive film contain a metal being different from the metal of the plurality of electrode layers.

8. The device according to claim 1, further comprising an insulating film provided between the first conductive film and the charge storage film and between the second conductive film and the charge storage film, and being in contact with the first conductive film and the second conductive film, wherein
the insulating film contains at least any one of hafnium, aluminum, zirconium, and lanthanum.

9. The device according to claim 1, wherein
the first conductive film includes:
a first face being in contact with a side surface of the first electrode layer; and
a second face opposite to the first face,
the second conductive film includes:
a third face being in contact with a side surface of the second electrode layer; and
a fourth face opposite to the third face,
a distance between the first face and the second face is larger than one-half of a thickness of the first electrode layer in contact with the first face, and
a distance between the third face and the fourth face is larger than one-half of a thickness of the second electrode layer in contact with the third face.

10. The device according to claim 1, wherein
the first conductive film includes:
a first face being in contact with a side surface of the first electrode layer; and
a second face opposite to the first face,
the second conductive film includes:
a third face being in contact with a side surface of the second electrode layer; and
a fourth face opposite to the third face,
a distance between the first face and the second face is 5 nm or less, and
a distance between the third face and the fourth face is 5 nm or less.

11. The device according to claim 1, wherein
the first conductive film and the second conductive film contain a metal nitride, and
an atomic number ratio of nitrogen atom to metal atom in the metal nitride is 0.1 or more and 2.0 or less.

12. The device according to claim 1, wherein a first distance between the first insulating layer and the semiconductor portion is smaller than a second distance between the first electrode layer and the semiconductor portion, and between the second electrode layer and the semiconductor portion.

13. The device according to claim 12, wherein
the stacked body includes a second insulating layer provided relative to the first insulating layer via the first electrode layer and being in contact with the first electrode layer, and
the first conductive film is in contact with a side surface of the first electrode layer, is provided between the first insulating layer and the second insulating layer, and is in contact with the second insulating layer.

14. The device according to claim 13, wherein a third distance between the first conductive film and the semiconductor portion, and between the second conductive film and the semiconductor portion is smaller than the second distance, and is not smaller than the first distance.

15. The device according to claim 1, wherein the charge storage film does not extend to a plane crossing the stacking direction.

16. The device according to claim 1, wherein
the first insulating layer includes:
a first insulating portion being in contact with the first electrode layer;
a second insulating portion being in contact with the first conductive film and the second conductive film, and extending in the stacking direction; and
a third insulating portion separated from the first insulating portion in the stacking direction, being in contact with the second electrode layer, and being connected to the first insulating portion via the second insulating portion.

17. The device according to claim 1, wherein
the first conductive film is provided extending in the stacking direction and includes an upper surface in contact with the first insulating layer, and
a face in contact with the insulating layer of the first electrode layer is coplanar with a face in contact with the insulating layer of the upper surface.

18. A method for manufacturing a semiconductor memory device, comprising:
forming a stacked body including a plurality of electrode layers containing a metal and stacked via an insulating layer;
forming a hole piercing the stacked body and extending in a stacking direction of the stacked body;
forming a plurality of conductive films being in contact with a side surface of the plurality of electrode layers through the hole;
forming a film including a charge storage film on a side wall of the hole; and
forming a semiconductor portion on an inside of the film including the charge storage film.

19. The method according to claim 18, wherein the forming the conductive film includes:
forming a spaces by recessing the plurality of electrode layers through the hole; and
forming the conductive film in the spaces.

20. The method according to claim 19, wherein the forming the conductive film in the spaces includes annealing the stacked body and depositing a conductive film containing a metal nitride on side surfaces of the plurality of electrode layers exposed to the spaces.
